(19) United States
(12) Patent Application Publication
(10) Pub. No.: US 2011/0284861 A1
(43) Pub. Date: Nov. 24, 2011

(54) LOW-TEMPERATURE POLYSILICON THIN FILM AND METHOD OF MANUFACTURING THE SAME, TRANSISTOR, AND DISPLAY APPARATUS

(75) Inventors: Won Seok KIM, Beijing (CN); Pil Seok KIM, Beijing (CN)

(73) Assignees: CHENGDU BOE OPTOELECTRONICS TECHNOLOGY CO., LTD., Chengdu (CN); BOE TECHNOLOGY GROUP CO., LTD., Beijing (CN)

(21) Appl. No.: 13/109,356

(22) Filed: May 17, 2011

(30) Foreign Application Priority Data
May 18, 2010 (CN) 201010180971.0

(51) Int. Cl. H01L 33/16; H01L 29/04; H01L 29/786; H01L 21/20

(52) U.S. Cl. 257/72; 438/486; 257/75; 257/66; 257/E21.09; 257/E29.003; 257/E29.293; 257/E33.003

(57) ABSTRACT

A method for manufacturing a low-temperature polysilicon thin film comprises the steps of providing a substrate and forming a buffer layer on the substrate; forming a first amorphous silicon thin film on the buffer layer; forming catalyst particles on the first amorphous silicon thin film; forming a second amorphous silicon thin film to cover the first amorphous silicon thin film and the catalyst particles; and performing a crystallization of the first and second amorphous silicon thin films by using the catalyst particles so as to form the low-temperature polysilicon thin film.

### BACKGROUND

Embodiments of the present invention relates to a low-temperature polysilicon thin film and a method of manufacturing the same, a transistor, and a display apparatus.

With rapid development of flat panel display technology, active matrix organic light emitting diode displays (AMOLEDs) have become the future development trend of flat panel displays due to good characteristics, such as thin profile, self-illumination, and high reaction rate, etc.

An AMOLED may include an active switch layer, an insulating layer, transparent electrodes, a light-emitting layer and metal electrodes, which are sequentially formed on a base substrate. An active switch is connected to the corresponding transparent electrode through a contact hole so as to control the written of the image data. Currently, to realize large-scale AMOLED, the active switches typically adopt low-temperature polysilicon TFTs (LTPS-TFTs) as pixel switching control elements. The quality of the low-temperature polysilicon thin film used for manufacturing LIPS-TFTs governs the electrical performance of the manufactured LIPS-TFTs. Therefore, there is more attention paid on the technology for manufacturing low-temperature polysilicon thin films.

The metal induced crystallization (MIC) process without usage of laser can be employed to manufacture low-temperature polysilicon thin films. FIGS. 1-3 show the steps of a conventional MIC process.

FIG. 1 is a cross-sectional view showing the first step of the process for manufacturing a low-temperature polysilicon thin film; FIG. 2 is a second cross-sectional view showing the second step of the process for manufacturing the low-temperature polysilicon thin film; and FIG. 3 is a cross-sectional view showing the third step of the process for manufacturing the low-temperature polysilicon thin film.

Firstly, nickel particles 13 are formed on the surface of a buffer layer 12 formed on a glass substrate 11; then, an amorphous silicon (a-Si) layer 14 is disposed to cover the buffer layer 12 and the nickel particles 13; finally, the a-Si layer 14 is transformed into a polysilicon layer, which includes a plurality of polysilicon grains 15 grown with the nickel particles 13 as cores, by a crystallization process.

The distribution of the threshold voltage Vth of the LTPS-TFTs fabricated with the polysilicon layer manufactured by the above MIC process is relatively stable; however, the LTPS-TFTs fabricated with the polysilicon layer manufactured by the above MIC process has the following defects. During crystallization, the a-Si layer 14 and the nickel particles 13 will form Ni silicide at the contact surface 16 as shown in FIG. 3. During manufacturing the LTPS-TFTs, the contact surface 16 is used as a gate oxide interface. Since Ni silicide has a certain degree of conductivity, when the LTPS-TFTs fabricated with the polysilicon layer manufactured by the above MIC process is turned off, the current leakage in the channels of the LTPS-TFTS is increased due to the presence of Ni silicide. Thus, there is a large off-state current, and the LTPS-TFTs is unstable.

### SUMMARY

One embodiment of the present invention provides a method for manufacturing a low-temperature polysilicon thin film, comprising: providing a substrate and forming a buffer layer on the substrate; forming a first amorphous silicon thin film on the buffer layer; forming catalyst particles on the first amorphous silicon thin film; forming a second amorphous silicon thin film to cover the first amorphous silicon thin film and the catalyst particles; and performing a crystallization of the first and second amorphous silicon thin films by using the catalyst particles so as to form the low-temperature polysilicon thin film.

Another embodiment of the present invention provides a low-temperature polysilicon thin film formed by the above-mentioned method for manufacturing a low-temperature polysilicon thin film.

Still another embodiment of the present invention provides a low-temperature polysilicon thin film transistor, comprising: a base substrate; a semiconductor layer comprising the above-mentioned low-temperature polysilicon thin film and formed above the base substrate and comprising a source region, a drain region, and a channel region located between the source region and the drain region; a gate insulating layer and a gate electrode sequentially formed on the semiconductor region, wherein the gate electrode corresponds to the channel region; a dielectric layer formed on the gate electrode and the gate insulating layer and having first and second via holes formed therein, a source electrode connected to the source region through the first via hole, and a drain electrode connected to the drain region through the second via hole.

Still another embodiment of the present invention provides a display apparatus, comprising an array substrate, wherein the above-described low-temperature polysilicon thin film transistor is formed on the array substrate.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the following detailed description.

### BRIEF DESCRIPTION OF THE DRAWINGS

The present invention will become more fully understood from the detailed description given hereinafter and the accompanying drawings which are given by way of illustration only, and thus are not limitative of the present invention and wherein:

FIGS. 1-3 are cross-sectional views showing the steps of the processes for manufacturing a low-temperature polysilicon thin film;

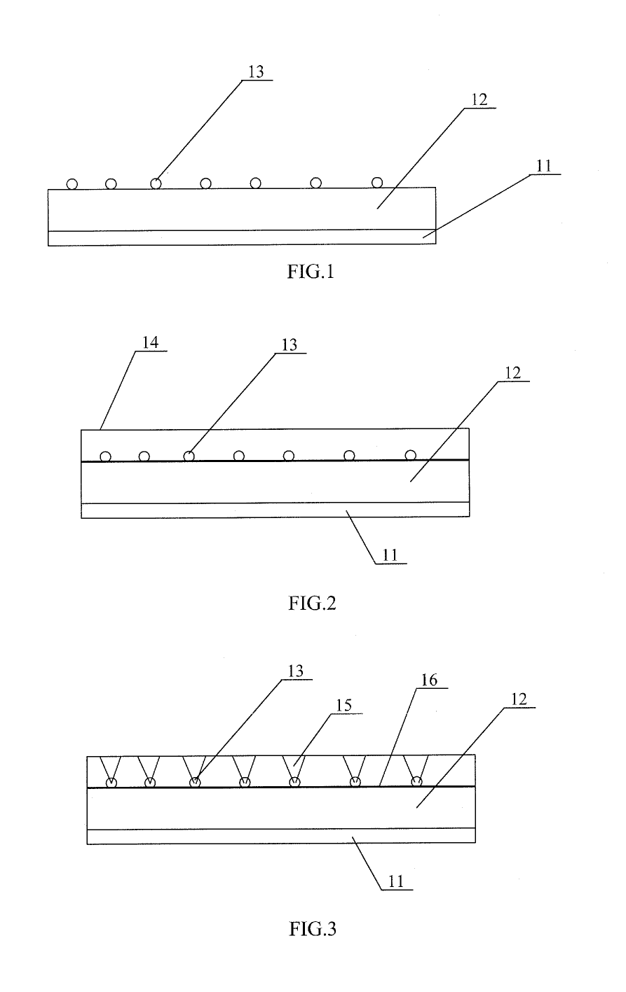

FIGS. 4-8 are cross-sectional views showing the processes for manufacturing the low-temperature polysilicon thin film according to an embodiment of the present invention; and

FIG. 9 is a schematic view of a thin film transistor according to an embodiment of the invention.

### DETAILED DESCRIPTION

Hereinafter, embodiments will be described in detail with reference to the accompanying drawings so that the objects, technical solutions and advantages of the embodiments will become more apparent. It should be noted that the embodiments described below are merely a portion of but not all of the embodiments of the invention, and thus various modifications, combinations or alterations can be made on the basis of the described embodiments without departing from the spirit and scope of the invention.

An embodiment of the present invention is to provide a process for manufacturing a low-temperature polysilicon thin film having interlayer grain growth silicon (IGS). A catalyst layer, such as nickel and the like, is formed in the middle of an a-Si layer, so that subsequentially formed Ni silicide is also located in the middle of the formed polysilicon layer, avoiding forming silicide (e.g., Ni silicide) at a gate oxide interface of the thin film transistor (TFT) manufactured with the polysilicon layer, and thus the off-state current of the TFT can be effectively restrained and the leakage current is prohibited in the transistor.

The embodiments of the present invention will be described in detail hereinafter by referring to the accompanying drawings.

### First Embodiment

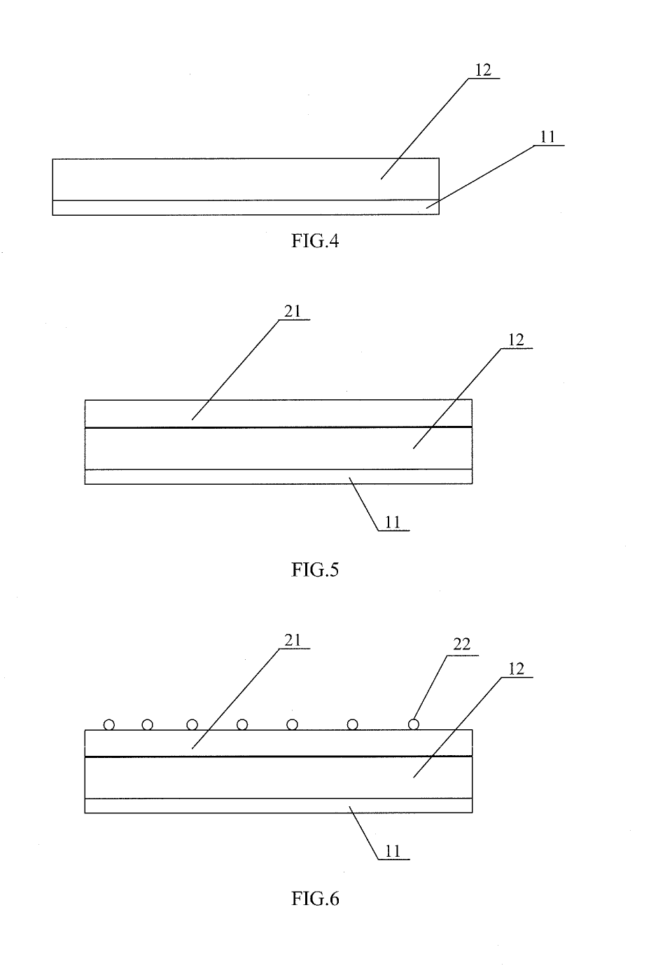

FIG. 4 is a cross-sectional view showing the first step of the processes for manufacturing the low-temperature polysilicon thin film according to a first embodiment; FIG. 5 is a cross-sectional view showing the second step of the processes for manufacturing the low-temperature polysilicon thin film according to the first embodiment; FIG. 6 is a cross-sectional view showing the third step of the processes for manufacturing the low-temperature polysilicon thin film according to first embodiment; FIG. 7 is a cross-sectional view showing the fourth step of the processes for manufacturing the low-temperature polysilicon thin film according to first embodiment; FIG. 8 is a cross-sectional view showing the fifth step of the processes for manufacturing the low-temperature polysilicon thin film according to first embodiment. By referring to the above drawings, the method according to the first embodiment includes the following steps.

Step 101: forming a buffer layer on a substrate.

With reference to FIG. 4, a substrate 11, which may be a glass substrate or plastic substrate, is provided. A buffer layer 12 is formed on the substrate 11. The buffer layer 12 may be an oxide layer, such as a silicon oxide layer, and is used for preventing the diffusion of the substance within the substrate 11, and such diffusion may reduces the quality of the fabricated low-temperature polysilicon thin film.

Step 102: depositing a first a-Si thin film layer on the buffer layer.

With reference to FIG. 5, a first a-Si thin film layer 21 is deposited on the buffer layer 12 by plasma enhanced chemical vapor deposition method or the like.

Step 103: forming catalyst particles above the first a-Si thin film layer.

With reference to FIG. 6, catalyst particles 22 are then formed by coating, plating or depositing on the first a-Si thin film layer 21. For example, the catalyst particles 22 may be extremely small particles of nickel. Further, the catalyst particles 22 can be any mixture of many kinds of metal, such as Cu, Al, Er, Cr, or Ni.

Step 104: depositing a second a-Si thin film layer.

With reference to FIG. 7, a second a-Si thin film layer 23 is formed on the first a-Si thin film layer and the catalyst particles 22. The second a-Si thin film layer 23 completely covers the catalyst particles 22. The method for forming the second a-Si thin film layer 23 may be same as that for forming the first a-Si thin film layer 21.

Step 105: performing crystallization on the above a-Si thin film layers, so that the a-Si thin film layers are crystallized to a low-temperature polysilicon thin film.

In this step, the above a-Si thin film layers can be crystallized by a rapid thermal annealing (RTA) process or a thermal annealing performed in a polysilicon forming furnace. With reference to FIG. 8, the a-Si thin film layers are transformed into a polysilicon thin film after the crystallization process. This polysilicon thin film includes the first polysilicon thin film layer 21′ and the second polysilicon thin film layer 23′, both of which include a plurality of polysilicon grains 24 grown with catalyst particles 22 as cores.

Since the catalyst particles 22 are located at the interface between the first polysilicon thin film layer 21′ and the second polysilicon thin film layer 23′, silicide such as Ni silicide formed by Ni particles 22 reacting with the a-Si thin film layers is also located at the interface between the layers, that is, in the middle portion of the formed polysilicon thin film layer, but not formed in the contact surface 16 between the formed polysilicon layer and the underlying buffer layer as shown in FIG. 3. Thus, the silicide (e.g., Ni silicide) does not influence the electrical characteristic of the LTPS-TFTs fabricated later with the polysilicon layer, and the current leakage of the transistors can be prevented effectively.

According to the method for manufacturing the low-temperature polysilicon thin film of the present embodiment, silicide (for example, Ni silicide) formed later is also located in the middle portion of the formed polysilicon layer by forming the catalyst layer, such as Ni and the like, in the middle portion of the a-Si thin film layer. The transistors formed of the low-temperature polysilicon thin film fabricated by the above method can have better Vth distribution, and the off-state current of the transistors can be prevented effectively.

### Second Embodiment

The present embodiment provides a low-temperature polysilicon thin film fabricated by the manufacture method of the low-temperature polysilicon thin film described in the first embodiment.

### Third Embodiment

The present embodiment provides a LTPS-TFT formed of the low-temperature polysilicon thin film of the second embodiment.

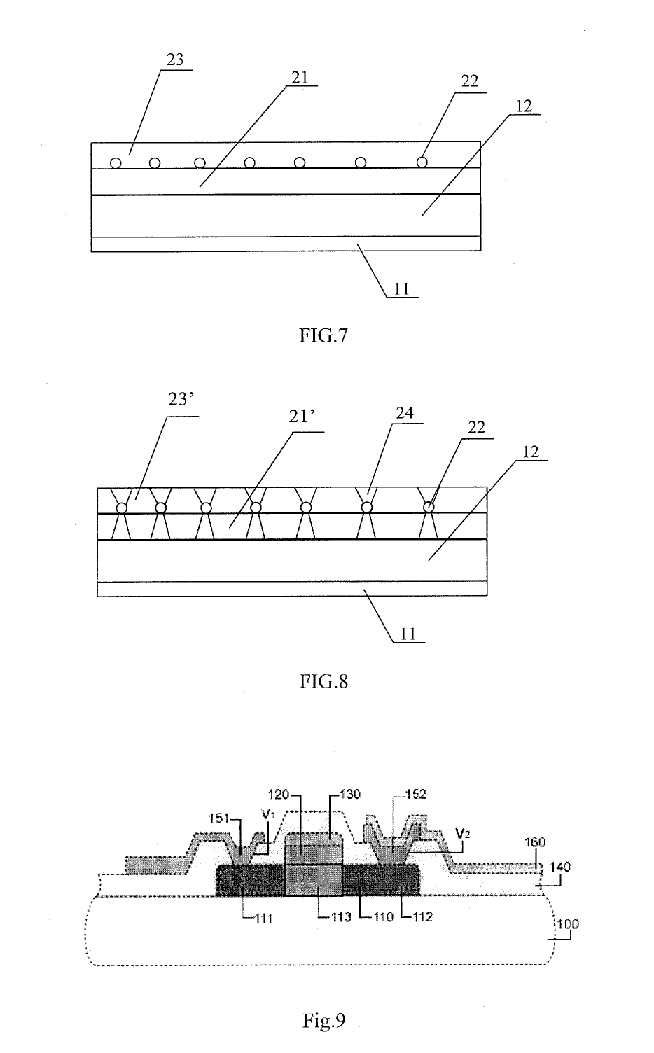

In detail, as shown in FIG. 9, the LTPS-TFT of the present embodiment includes a substrate 100, a semiconductor layer 110, a gate insulating layer 120, a gate electrode 130, a dielectric layer 140, a source electrode 151, and a drain electrode 152. The substrate 100 may be a glass substrate or a plastic substrate. The semiconductor layer 120 made of the low-temperature polysilicon thin film of the third embodiment is formed on the substrate 100 and includes a source region 111, a drain region 112, and a channel region 113 between the source region 111 and the drain region 112. The gate insulating layer 120 and the gate electrode 130 are sequentially formed on the semiconductor layer 110, and the gate electrode 130 corresponds to the channel region 113. The dielectric layer 140 is formed on the gate electrode 130 and the gate insulating layer 120 and has a first via hole V1 and a second via hole V2 formed therein. The source electrode 151 is connected to the source region 111 through the first via hole V1, and the drain electrode 152 is connected to the drain region 112 through the second via hole V2. The source and drain electrodes 151 and 152 are for example formed of a metal material.

The LTPS-TFT can be used as a switching element of a pixel of a thin film transistor liquid crystal display (TFT-LCD), and as shown in FIG. 9, a pixel electrode 160 is formed on the dielectric layer 140, and the pixel electrode 160 is electrically connected with the drain electrode 152. The pixel electrode 160 can be formed of a transparent conductive material such as indium tin oxide (ITO) or indium zinc oxide (IZO). The LTPS-TFT can also be used as a switching element for an organic light emitting diode display (OLED), in which the drain electrode of the LTPS-TFT is electrically connected with the cathode electrode of a pixel.

Since the LTPS-TFT of the present embodiment is made of the low-temperature polysilicon thin film in which the Ni silicide is located in the middle portion of the polysilicon layer, the channel region of the LTPS-TFT can have better threshold voltage distribution, and the off-state current can be prevented effectively.

### Fourth Embodiment

The embodiment of the present invention provides a display apparatus including an array substrate and LTPS-TFTs formed on the substrate. The LTPS-TFTs of the third embodiment are used as the above LTPS-TFTs as switching elements.

The display apparatus of the present embodiment may be an organic light emitting diode display (OLED) or a liquid crystal display (LCD), etc. Since the electrical property of the LTPS-TFTs used in the display apparatus are more stable and the off-state current can be prevented effectively, the display quality of the display apparatus is improved.

The above embodiments are described only for the purpose of illustrating the present invention, but not a limitation thereto. Although the invention is described in detail by referring to the embodiments set forth, it should be understood by those skilled in the art that various modifications to the embodiments set forth or various replacements of a part of the technical features can be made. Such modifications or replacements are not to be regarded as a departure from the spirit and scope of the embodiments of the present invention.

What is claimed is:

1. A method for manufacturing a low-temperature polysilicon thin film, comprising:
providing a substrate and forming a buffer layer on the substrate;
forming a first amorphous silicon thin film on the buffer layer;
forming catalyst particles on the first amorphous silicon thin film;
forming a second amorphous silicon thin film to cover the first amorphous silicon thin film and the catalyst particles; and
performing a crystallization of the first and second amorphous silicon thin films by using the catalyst particles so as to form the low-temperature polysilicon thin film.

2. The method for manufacturing a low-temperature polysilicon thin film of claim 1, wherein the buffer layer formed on the substrate comprises a silicon oxide layer.

3. The method for manufacturing a low-temperature polysilicon thin film of claim 1, wherein the catalyst particles comprises particles of Ni, Cu, Al, Er, or Cr.

4. The method for manufacturing a low-temperature polysilicon thin film of claim 1, wherein the crystallization comprises a rapid heat treatment.

5. A low-temperature polysilicon thin film formed by the method for manufacturing a low-temperature polysilicon thin film of claim 1.

6. A low-temperature polysilicon thin film transistor, comprising:
a base substrate;
a semiconductor layer comprising the low-temperature polysilicon thin film of claim 5 and formed above the base substrate and comprising a source region, a drain region, and a channel region located between the source region and the drain region;
a gate insulating layer and a gate electrode sequentially formed on the semiconductor region, wherein the gate electrode corresponds to the channel region;
a dielectric layer formed on the gate electrode and the gate insulating layer and having first and second via holes formed therein,
a source electrode connected to the source region through the first via hole, and
a drain electrode connected to the drain region through the second via hole.

7. A display apparatus, comprising an array substrate,
wherein the low-temperature polysilicon thin film transistor of claim 6 is formed on the array substrate.

8. The display apparatus of claim 7, wherein the display apparatus is an active matrix organic light emitting diode display apparatus or a liquid crystal display apparatus.
